(19) United States
(12) Patent Application Publication
(10) Pub. No.: US 2019/0033407 A1
(43) Pub. Date: Jan. 31, 2019

(54) MAGNETIC RESONANCE IMAGING APPARATUS AND METHOD OF GENERATING MAGNETIC RESONANCE IMAGE

(71) Applicant: SAMSUNG ELECTRONICS CO., LTD., Suwon-si (KR)

(72) Inventors: Hyun-seok SEO, Seoul (KR); Dae-ho LEE, Seongnam-si (KR); Joon-soo KIM, Seoul (KR)

(73) Assignee: SAMSUNG ELECTRONICS CO., LTD., Suwon-si (KR)

(21) Appl. No.: 16/033,387

(22) Filed: Jul. 12, 2018

(30) Foreign Application Priority Data
Jul. 31, 2017 (KR) 10-2017-0097130

(51) Int. Cl. G01R 33/483; G01R 33/565

(52) U.S. Cl. CPC G01R 33/4835; G01R 33/56545

(57) ABSTRACT

A magnetic resonance imaging (MRI) apparatus includes a processor; and a memory connected to the processor and storing an instruction that, when executed by the processor, causes the processor to acquire a first magnetic resonance signal by applying a first pulse sequence to a plurality of slices of an object, acquire a second magnetic resonance signal by applying a second pulse sequence to the plurality of slices, and generate a multi-slice image, based on an average value of the acquired first magnetic resonance signal and the acquired second magnetic resonance signal.

### CROSS-REFERENCE TO RELATED APPLICATION(S)

This application is based on and claims priority under 35 U.S.C. § 119 to Korean Patent Application No. 10-2017-0097130, filed on Jul. 31, 2017, in the Korean Intellectual Property Office, the disclosure of which is incorporated by reference herein in its entirety.

### BACKGROUND

### 1. Field

The disclosure relates to a magnetic resonance imaging (MRI) apparatus, and a method of generating a magnetic resonance image. More particularly, the present disclosure relates to an MRI apparatus for generating a magnetic resonance image, based on multi-slice imaging, and a magnetic resonance image generating method performed by the MRI apparatus.

### 2. Description of Related Art

Magnetic resonance imaging (MRI) apparatuses are apparatuses for capturing images of an inside of an object by using a magnetic field, and are widely used to accurately diagnose a disease because the MRI apparatuses three-dimensionally show not only bones, but may also show discs, joints, nerves, ligaments, and the heart at a desired angle.

When an MRI apparatus scans a patient by using a spin echo sequence, non-uniformity of a magnetic field, or non-uniformity of a magnetic field due to non-uniformity of a body tissue may be compensated for, thus reducing image degradation. Accordingly, a spin echo sequence is widely used not only in the brain, but also throughout the abdomen and extremities.

A two-dimensional (2D) MRI technique of obtaining image data of a plurality of cross-sections during one repetition time (TR) is referred to as multi-slice imaging. When an image is obtained by multi-slice imaging, images of several cross-sections can be obtained during a time period taken to obtain a single cross-section, and thus a total image acquisition time may be reduced.

According to multi-slice imaging, pulse sequences may be applied to a plurality of slices in this stated order or in a determined order. Because a pulse sequence that is applied to one of the plurality of slices may also affect slices adjacent thereto, an image obtained by multi-slice imaging may have artifacts due to the adjacent slices.

### SUMMARY

Provided are methods and apparatuses which may be used to generate a magnetic resonance image from which artifacts due to signals of adjacent slices have been removed, when a multi-slice magnetic resonance image of an object is captured.

Additional aspects will be set forth in part in the description which follows and, in part, will be apparent from the description, or may be learned by practice of the presented embodiments.

In accordance with an aspect of the disclosure, a magnetic resonance imaging (MRI) apparatus includes a processor, and a memory connected to the processor and configured to store an instruction which, when executed by the processor, causes the processor to acquire a first magnetic resonance signal by applying a first pulse sequence to a plurality of slices of an object, acquire a second magnetic resonance signal by applying a second pulse sequence to the plurality of slices, and generate a multi-slice image, based on an average value of the acquired first magnetic resonance signal and the acquired second magnetic resonance signal. The first pulse sequence comprises a first spin echo sequence including a first 90° radio frequency (RF) pulse and a first 180° RF pulse applied to each of the plurality of slices according to an order of the plurality of slices in a space where the plurality of slices are located, and the second pulse sequence comprises a second spin echo sequence including a second 90° RF pulse and a second 180° RF pulse applied to each of the plurality of slices according to the order of the plurality of slices in the space where the plurality of slices are located. The second 90° RF pulse is applied having opposite signs to adjacent slices from among the plurality of slices, and the second 180° RF pulse is applied having opposite signs to the adjacent slices from among the plurality of slices.

A sign of the first 90° RF pulse may be applied having same signs to the adjacent slices from among the plurality of slices, and a sign of the first 180° RF pulse may be applied having same signs to the adjacent slices from among the plurality of slices.

The memory may be further configured to store an instruction which, when executed by the processor, causes the processor to receive a plurality of first echo signals corresponding to the plurality of slices according to the order of the plurality of slices in the space where the plurality of slices are located, by applying the first pulse sequence to the plurality of slices, and receive a plurality of second echo signals corresponding to the plurality of slices according to the order of the plurality of slices in the space where the plurality of slices are located, by applying the second pulse sequence to the plurality of slices, and the MRI apparatus may further include a signal receiver configured to receive the first echo signal and the second echo signal.

The memory may be further configured to store an instruction which, when executed by the processor, causes the processor to receive second echo signals corresponding to the adjacent slices in opposite directions when receiving the plurality of second echo signals.

The MRI apparatus may further include an analog-to-digital converter (ADC) configured to perform analog-to-digital conversion with respect to the plurality of first echo signals and the plurality of second echo signals received by the signal receiver.

The memory may be further configured to store an instruction which, when executed by the processor, causes the processor to display a phase of a spin according to at least a portion of the first pulse sequence.

The memory may be further configured to store an instruction which, when executed by the processor, causes the processor to acquire a first magnetic resonance signal corresponding to an (N-2)th slice, a first magnetic resonance signal corresponding to an (N-1)th slice, and a first magnetic resonance signal corresponding to an N-th slice by sequentially applying the first pulse sequence to the (N-2)th slice, the (N-1)th slice, and the N-th slice, and the first magnetic resonance signal corresponding to the N-th slice may include a first artifact signal generated by the first 90° RF pulse and the first 180° RF pulse applied to the (N-2)th slice and the (N-1)th slice.

The memory may be further configured to store an instruction which, when executed by the processor, causes the processor to acquire a second magnetic resonance signal corresponding to the (N-2)th slice, a second magnetic resonance signal corresponding to the (N-1)th slice, and a second magnetic resonance signal corresponding to the Nth slice by sequentially applying the second pulse sequence to the (N-2)th slice, the (N-1)th slice, and the Nth slice, the second magnetic resonance signal for the N-th slice may include a second artifact signal generated by the second 90° RF pulse and the second 180° RF pulse applied to the (N-2)th slice and the (N-1)th slice, and the first artifact signal may correspond to a first piece of k-space data, the second artifact signal may correspond to a second piece of k-space data, a sign of the first piece of k-space data may be opposite to a sign of the second piece of k-space data, and a magnitude of the first piece of k-space data may be equal to a magnitude of the second piece of k-space data.

An in-phase time of spins corresponding to the first artifact signal may correspond to an in-phase time of spins corresponding to the second artifact signal.

The MRI apparatus may further include a display, and the memory may be further configured to store an instruction which, when executed by the processor, causes the processor to control the display to display the generated multi-slice image.

In accordance with an aspect of the disclosure, a method of generating a magnetic resonance image from which an artifact due to a signal of adjacent slices has been removed, when a multi-slice magnetic resonance image of an object is captured, the method including acquiring a first magnetic resonance signal by applying a first pulse sequence to a plurality of slices of the object, acquiring a second magnetic resonance signal by applying a second pulse sequence to the plurality of slices, and generating the multi-slice magnetic resonance image, based on an average value of the acquired first magnetic resonance signal and the acquired second magnetic resonance signal. The first pulse sequence comprises a first spin echo sequence including a first 90° radio frequency (RF) pulse and a first 180° RF pulse applied to each of the plurality of slices according to an order of the plurality of slices in a space where the plurality of slices are located, and the second pulse sequence comprises a second spin echo sequence including a second 90° RF pulse and a second 180° RF pulse applied to each of the plurality of slices according to the order of the plurality of slices in the space where the plurality of slices are located. The second 90° RF pulse is applied having opposite signs to adjacent slices from among the plurality of slices, and the second 180° RF pulse is applied having opposite signs to the adjacent slices from among the plurality of slices.

A sign of the first 90° RF pulse may be applied having same signs to the adjacent slices from among the plurality of slices, and a sign of the first 180° RF pulse may be applied having same signs to the adjacent slices from among the plurality of slices.

The acquiring of the first magnetic resonance signal may include receiving, from a signal receiver, a plurality of first echo signals corresponding to the plurality of slices according to the order of the plurality of slices in the space where the plurality of slices are located, by applying the first pulse sequence to the plurality of slices, and the acquiring of the second magnetic resonance signal may include receiving, from the signal receiver, a plurality of second echo signals corresponding to the plurality of slices according to the order of the plurality of slices in the space where the plurality of slices are located, by applying the second pulse sequence to the plurality of slices.

The receiving of the second echo signal may include receiving second echo signals corresponding to the adjacent slices in opposite directions when receiving the plurality of second echo signals.

The method may further include performing analog-to-digital conversion on the received plurality of first echo signals using an analog-to-digital converter (ADC), and performing analog-to-digital conversion on the received plurality of second echo signals using the ADC.

The method may further include displaying a phase of a spin according to at least a portion of the first pulse sequence.

The acquiring of the first magnetic resonance signal may include acquiring the a first magnetic resonance signal corresponding to an (N-2)th slice, a first magnetic resonance signal corresponding to an (N-1)th slice, and a first magnetic resonance signal corresponding to an N-th slice by sequentially applying the first pulse sequence to the (N-2)th slice, the (N-1)th slice, and the N-th slice, and the first magnetic resonance signal corresponding to the N-th slice may include a first artifact signal generated by the first 90° RF pulse and the first 180° RF pulse applied to the (N-2)th slice and the (N-1)th slice.

The acquiring of the second magnetic resonance signal may include acquiring a second magnetic resonance signal corresponding to the (N-2)th slice, a second magnetic resonance signal corresponding to the (N-1)th slice, and a second magnetic resonance signal corresponding to the N-th slice by sequentially applying the second pulse sequence to the (N-2)th slice, the (N-1)th slice, and the N-th slice, the second magnetic resonance signal for the N-th slice may include a second artifact signal generated by the second 90° RF pulse and the second 180° RF pulse applied to the (N-2)th slice and the (N-1)th slice, and the first artifact signal may correspond to a first piece of k-space data, the second artifact signal may correspond to a second piece of k-space data, a sign of the first piece of k-space data may be opposite to a sign of the second piece of k-space data, and a magnitude of the first piece of k-space data may be equal to a magnitude of the second piece of k-space data.

An in-phase time of spins corresponding to the first artifact signal may correspond to an in-phase time of spins corresponding to the second artifact signal.

In accordance with an aspect of the disclosure, a computer program product including a non-transitory computer-readable recording medium may have recorded thereon a computer program, which, when executed by a computer, causes the computer to perform the methods described herein.

In accordance with an aspect of the disclosure, a method of generating a magnetic resonance image includes acquiring a first magnetic resonance signal by applying a first spin echo sequence including a first 90° radio frequency (RF) pulse and a first 180° RF pulse to a first slice of an object and a second slice of the object, wherein the first slice is adjacent to the second slice, acquiring a second magnetic resonance signal by applying a second spin echo sequence including a second 90° RF pulse and a second 180° RF pulse to the first slice and the second slice, and generating a multi-slice magnetic resonance image, based on an average value of the acquired first magnetic resonance signal and the acquired second magnetic resonance signal, wherein a sign of the first 90° RF pulse is equal to a sign of the first 180° RF pulse, and wherein a sign of the second 90° RF pulse is opposite to a sign of the second 180° RF pulse.

### BRIEF DESCRIPTION OF THE DRAWINGS

The above and other aspects, features, and advantages of certain embodiments of the present disclosure will be more apparent from the following description taken in conjunction with the accompanying drawings, in which:

FIGS. 1A through 1C are views for explaining acquisition of a magnetic resonance image according to multi-slice imaging, according to an embodiment;

FIGS. 2A through 2C are views for illustrating a sequence in which pieces of magnetic resonance signal data for a plurality of slices are acquired when a magnetic resonance image is acquired by multi-slice imaging, according to an embodiment;

FIG. 3 is a graph for explaining interference between pieces of data about a plurality of slices when a magnetic resonance image is acquired by multi-slice imaging, according to an embodiment;

FIG. 4 is a block diagram of a magnetic resonance imaging (MRI) apparatus according to an embodiment;

FIG. 5 is a view for explaining an echo path of an artifact signal generated by a radio frequency (RF) pulse applied by the MRI apparatus according to an embodiment;

FIG. 6 is a view for explaining an echo path of an artifact signal generated by an RF pulse applied by the MRI apparatus according to an embodiment;

FIG. 7A is a diagram for illustrating a first pulse sequence that is used by the MRI apparatus according to an embodiment;

FIG. 7B is a diagram for illustrating a second pulse sequence that is used by the MRI apparatus according to an embodiment;

FIG. 8A illustrates pieces of k-space data respectively corresponding to a first magnetic resonance signal and a second magnetic resonance signal obtained by the MRI apparatus according to an embodiment;

FIG. 8B illustrates pieces of k-space data respectively corresponding to a first magnetic resonance signal and a second magnetic resonance signal obtained by the MRI apparatus according to an embodiment;

FIG. 9A illustrates a plurality of sectional images acquired based on a first magnetic resonance signal by the MRI apparatus according to an embodiment;

FIG. 9B illustrates a plurality of sectional images acquired based on an average value of first and second magnetic resonance signals by the MRI apparatus according to an embodiment; and

FIG. 10 is a flowchart of a method, performed by the MRI apparatus according to an embodiment, of generating a magnetic resonance image, according to an embodiment.

FIG. 11 is a schematic diagram of an MRI system according to an embodiment.

### DETAILED DESCRIPTION

The present specification describes principles of the present disclosure and sets forth embodiments thereof to clarify the scope of the present disclosure and to allow those of ordinary skill in the art to implement the embodiments. The present embodiments may have different forms.

Like reference numerals refer to like elements throughout. The present specification does not describe all components in the embodiments, and common knowledge in the art or the same descriptions of the embodiments will be omitted below. The term “part” or “portion” may be implemented using hardware or software, and according to embodiments, one “part” or “portion” may be formed as a single unit or element or include a plurality of units or elements. Hereinafter, the principles and embodiments of the present disclosure will be described in detail with reference to the accompanying drawings.

In the present specification, an “image” may include a medical image obtained by a magnetic resonance imaging (MRI) apparatus, a computed tomography (CT) apparatus, an ultrasound imaging apparatus, an X-ray apparatus, or another medical imaging apparatus.

Furthermore, in the present specification, an “object” may be a target to be imaged and include a human, an animal, or a part of a human or animal. For example, the object may include a body part, for example an organ, or a phantom.

An MRI system acquires a magnetic resonance signal and reconstructs the acquired magnetic resonance signal into an image. The magnetic resonance signal denotes a radio frequency (RF) signal emitted from the object.

In the MRI system, a main magnet creates a static magnetic field to align a magnetic dipole moment of a specific atomic nucleus of the object placed in the static magnetic field along a direction of the static magnetic field. A gradient coil may generate a gradient magnetic field by applying a gradient signal to a static magnetic field and induce resonance frequencies differently according to each region of the object.

An RF coil may emit an RF signal to match a resonance frequency of a region of the object whose image is to be acquired. Furthermore, when gradient magnetic fields are applied, the RF coil may receive magnetic resonance signals having different resonance frequencies emitted from a plurality of regions of the object. Though this process, the MRI system may obtain an image from a magnetic resonance signal by using an image reconstruction technique.

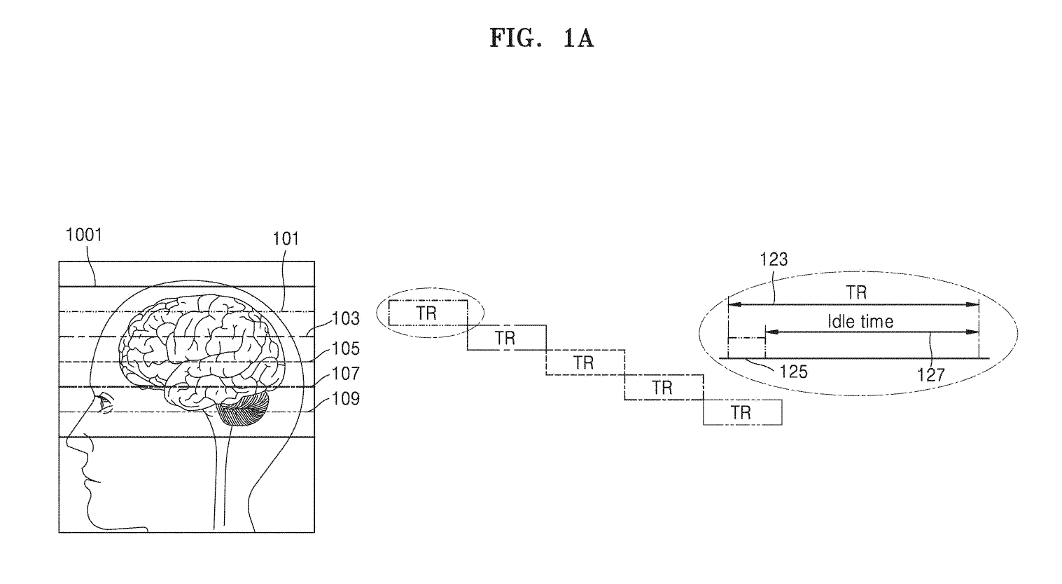

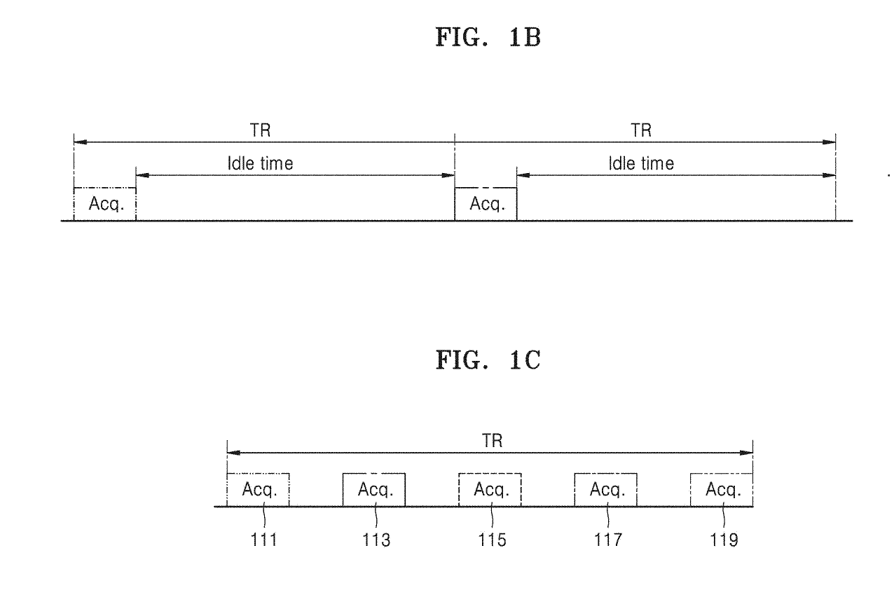

FIGS. 1A through 1C are views for explaining acquisition of a magnetic resonance image according to multi-slice imaging.

FIG. 1A illustrates scanning of an area 1001 including a plurality of slices, namely, first slice 101, second slice 103, third slice 105, fourth slice 107, and fifth slice 109 of an object, according to an embodiment.

Referring to FIG. 1A, a repetition time (TR) 123 corresponding to the first slice 101 may include an acquisition time 125 during which an RF pulse is applied to the first slice 101 and a magnetic resonance signal generated due to the application of the RF pulse is acquired, and an idle time 127 during which an influence of the RF pulse applied to the first slice 101 is reduced.

FIG. 1B illustrates a plurality of TRs corresponding to the first slice 101, second slice 103, third slice 105, fourth slice 107, and fifth slice 109, according to an embodiment.

During the plurality of TRs, RF pulses may be sequentially applied to the plurality of slices. For example, an RF pulse may be applied to only one slice during a TR for one slice.

Referring to FIG. 1C, during a single TR, instead of an RF pulse being applied to only one slice, RF pulses are sequentially applied to a plurality of slices, and thus a total scan time may be reduced.

For example, during a first acquisition time 111, as an RF pulse is applied to the first slice 101, a magnetic resonance signal for the first slice 101 may be acquired. During a second acquisition time 113, as an RF pulse is applied to the second slice 103, which is not affected by the RF pulse applied during the first acquisition time 111, a magnetic resonance signal for the second slice 103 may be acquired. Similarly, during a third acquisition time 115, a fourth acquisition time 117, and a fifth acquisition time 119, magnetic resonance signals for the third slice 105, the fourth slice 107, and the fifth slice 109 may be acquired.

Assuming that an ideal RF pulse is applied, the RF pulse should affect only one slice. However, because an actual RF pulse is not a perfect square wave, the actual RF pulse may also affect slides near a slice to which the actual RF pulse is applied.

When an image of a knee joint or a musculoskeletal object of which slices are close to each other is acquired, a relatively large amount of interference may be generated between pieces of data of adjacent slices.

As such, an artifact due to interference between pieces of data of adjacent slices may occur in a magnetic resonance image acquired by multi-slice imaging.

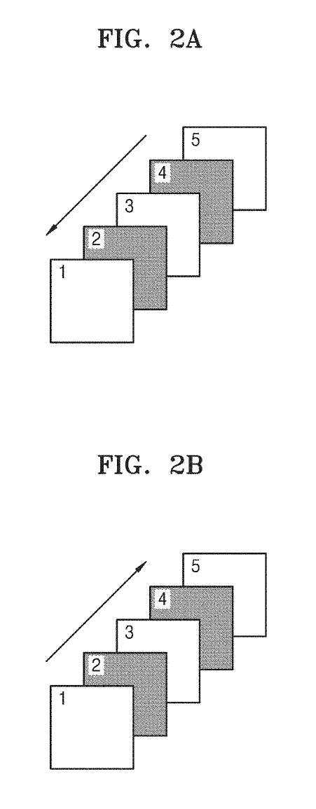

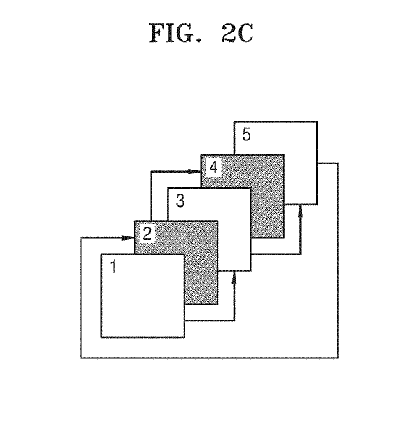

FIGS. 2A through 2C are views for illustrating a sequence in which pieces of magnetic resonance signal data for a plurality of slices are acquired when a magnetic resonance image is acquired by multi-slice imaging.

FIG. 2A illustrates a descending order method of acquiring pieces of magnetic resonance signal data for a plurality of cross-sections from top to bottom, according to an embodiment.

FIG. 2B illustrates an ascending order method of acquiring pieces of magnetic resonance signal data for a plurality of cross-sections from bottom to top, according to an embodiment.

FIG. 2C illustrates an acquisition method by which magnetic resonance signal data for even-numbered cross-sections are first acquired and magnetic resonance signal data for odd-numbered cross-sections are next acquired, according to an embodiment.

According to the acquisition method of FIG. 2C, an artifact due to interference between pieces of data of adjacent slices may be reduced.

It may be difficult to completely remove an artifact due to interference between pieces of data of slices even when the acquisition method illustrated in FIG. 2C is used. When a magnetic resonance image including a blood vessel is acquired using the acquisition method of FIG. 2C, it may be difficult to compensate for a signal based on a blood flow that affects a magnetic resonance image signal.

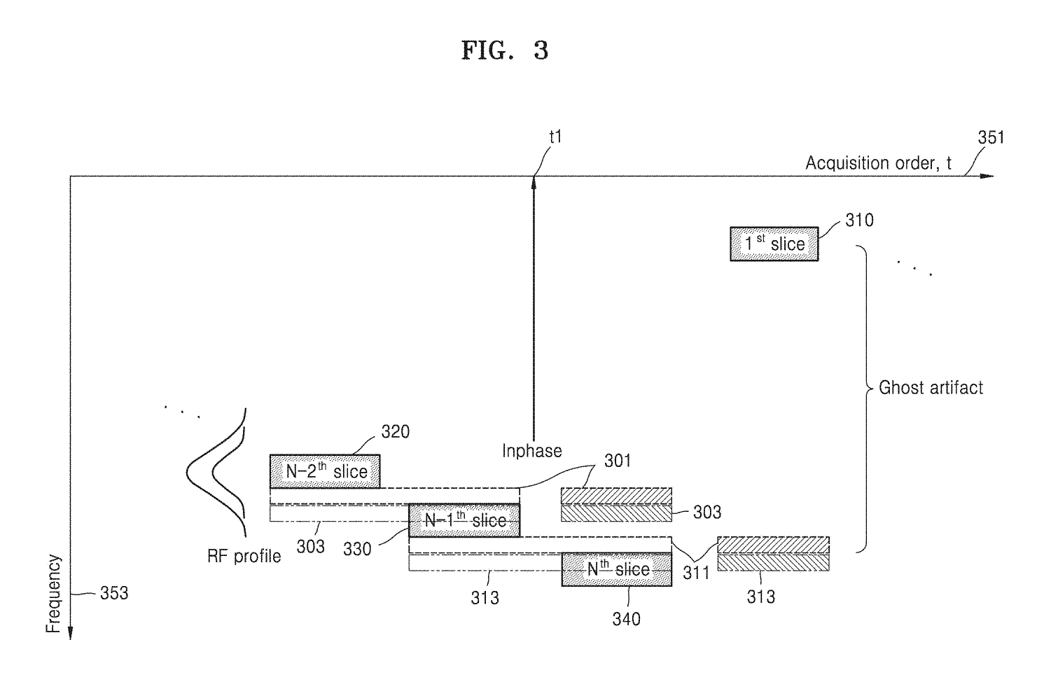

FIG. 3 is a graph for explaining interference between pieces of data about a plurality of slices when a magnetic resonance image is acquired by multi-slice imaging, according to an embodiment.

FIG. 3 illustrates a case of acquiring pieces of magnetic resonance signal data for a plurality of cross-sections in a descending order.

A first slice 310, an (N-2)th slice 320, an (N-1)th slice 330, and an Nth slice 340 of FIG. 3 may correspond to volume areas.

Thicknesses of the first slice 310, the (N-2)th slice 320, the (N-1)th slice 330, and the Nth slice 340 may be set differently from each other, for example according to different parts of an object to be scanned.

A horizontal axis 351 indicates an order in which slices are acquired, and a vertical axis 353 indicates a location of a cross-section and a frequency corresponding to the location.

Referring to FIG. 3, when a 90° RF pulse and a 180° RF pulse are applied to the (N-2)th slice 320, the 90° RF pulse and the 180° RF pulse applied to the (N-2)th slice 320 may also affect a portion around the (N-2)th slice 320.

In detail, the 90° RF pulse applied to the (N-2)th slice 320 may excite a spin of a first portion 301 near the (N-2)th slice 320.

The 180° RF pulse applied to the (N-2)th slice 320 may excite spins of the first portion 301 and a second portion 303 near the (N-2)th slice 320. The 180° RF pulse may affect a wider area than the 90° RF pulse does.

After data about the (N-2)th slice 320 is acquired, the 90° RF pulse and the 180° RF pulse applied to the (N-1)th slice 330 may also affect a portion around the (N-1)th slice 330.

In detail, the 90° RF pulse applied to the (N-1)th slice 330 may excite spins of the first portion 301, the second portion 303, and a third portion 311 near the (N-1)th slice 330.

The 180° RF pulse applied to the (N-1)th slice 330 may excite spins of the first portion 301, the second portion 303, the third portion 311, and a fourth portion 313 near the (N-1)th slice 330.

The 90° RF pulse and the 180° RF pulse applied to the (N-2)th slice 320 and the 90° RF pulse and the 180° RF pulse applied to the (N-1)th slice 330 excite the spin of the first portion 301, and the 180° RF pulse applied to the (N-2)th slice 320 and the 90° RF pulse and the 180° RF pulse applied to the (N-1)th slice 330 excite the spin of the second portion 303.

Accordingly, at a time point t1, the spin of the first portion 301 and the spin of the second portion 303 are in an in-phase state. The in-phase refers to returning of the phases of spins to a reference phase (=0). When spins are in an in-phase state, a magnetic resonance signal has a greatest magnitude. Accordingly, in-phase appearing at the time point t1 includes unintended in-phase corresponding to an artifact signal of the spins of the first portion 301 and the spins of the second portion 303.

When data about the Nth slice 340 is acquired, an artifact due to unintended in-phase at the time point t1 may be included.

According to an embodiment, to improve the quality of an image, data of the first slice 310 to the Nth slice 340 may be acquired in the descending order, and then the acquisition of the data of the first slice 310 to the Nth slice 340 in the descending order may be repeated.

At this time, an influence upon the spins of the third portion 311 and the fourth portion 313 when data about the Nth slice 340 is acquired may appear as a ghost artifact when data about the first slice 310 is acquired after data about the Nth slice 340 is acquired.

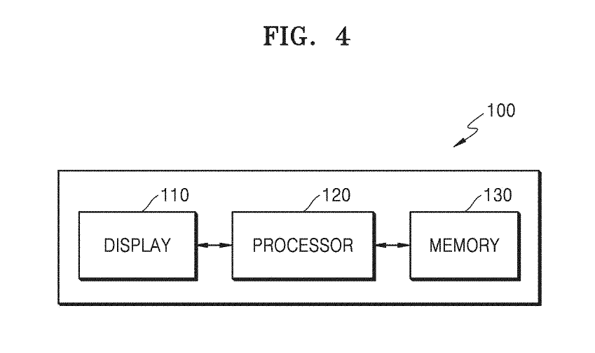

FIG. 4 is a block diagram of an MRI apparatus 100 according to an embodiment of the present disclosure.

The MRI apparatus 100 may be an apparatus for obtaining a 2D magnetic resonance image of an object according to multi-slice imaging, based on a spin echo pulse sequence. The MRI apparatus 100 may obtain an image signal for an object from which an artifact generated based on pieces of data between adjacent slices has been removed.

Referring to FIG. 4, the MRI apparatus 100 includes a display 110, a processor 120, and a memory 130.

The MRI apparatus 100 may be an apparatus connected to an MRI apparatus to control the MRI apparatus. For example, the MRI apparatus 100 may be included in a console for controlling an MRI apparatus.

When the MRI apparatus 100 is an MRI apparatus, the display 110 may be included in the MRI apparatus. The display 110 may be attached to the MRI apparatus 100.

The processor 120 according to an embodiment may execute an instruction stored in the memory 130.

The processor 120 may be configured to obtain a magnetic resonance image, based on magnetic resonance signal data stored in the memory 130 or magnetic resonance signal data received from an external device. For example, the magnetic resonance signal data may include a magnetic resonance signal received from a scanner.

The memory 130 according to an embodiment may store instructions executed by the processor 120.

For example, the memory 130 may store various pieces of data, programs, or applications for driving and controlling the MRI apparatus 100. A program stored in the memory 130 may include at least one instruction. A program or application stored in the memory 130 may be executed by the processor 120.

The memory 130 may store an instruction for obtaining a first magnetic resonance signal by applying a first pulse sequence to a plurality of slices of an object, obtaining a second magnetic resonance signal by applying a second pulse sequence to the plurality of slices of the object, and generating a multi-slice image based on an average value of the obtained first and second magnetic resonance signals.

The first pulse sequence and the second pulse sequence may be spin echo sequences including the 90° RF pulse and the 180° RF pulse applied to each of the plurality of slices according to a particular order on a space in which the plurality of slices are located.

The 90° RF pulse and the 180° RF pulse included in the first pulse sequence according to an embodiment may have the same sign when applied to adjacent slices from among the plurality of slices.

The 90° RF pulse and the 180° RF pulse included in the second pulse sequence according to an embodiment may have opposite signs when applied to adjacent slices from among the plurality of slices.

The memory 130 according to an embodiment may further store an instruction for receiving a first echo signal corresponding to each of the plurality of slices according to the order from the space in which the plurality of slices are located, by applying the first pulse sequence to the plurality of slices.

The memory 130 may further store an instruction for receiving a second echo signal corresponding to each of the plurality of slices according to the order from the space in which the plurality of slices are located, by applying the second pulse sequence to the plurality of slices.

The MRI apparatus 100 may further include a signal receiver for receiving the first echo signal and the second echo signal. For example, the signal receiver may have a function of transmitting and receiving an RF signal.

The MRI apparatus 100 may further include an analog-to-digital converter (ADC) that performs analog-to-digital conversion with respect to the first echo signal and the second echo signal received by the signal receiver.

The memory 130 may further store an instruction allowing the signal receiver to receive second echo signals respectively corresponding to adjacent slices in opposite directions when receiving second echo signals respectively corresponding to the plurality of slices.

For example, an instruction allowing the signal receiver to receive echo signals in opposite directions may include an instruction for changing the phase value of an echo signal acquired by the signal receiver.

The memory 130 may further store an instruction for displaying the phase of a spin according to at least a portion of the first pulse sequence. For example, the phase of the spin may be displayed to track an echo path.

The memory 130 may further store an instruction for displaying the generated multi-slice image. The memory 130 may further store an instruction for displaying at least one of the first and second pulse sequences.

The memory 130 may further store an instruction for obtaining a first magnetic resonance signal for an (N-2)th slice, an (N-1)th slice, and an Nth slice by sequentially applying the first pulse sequence to the (N-2)th slice, the (N-1)th slice, and the Nth slice.

The first magnetic resonance signal for the Nth slice may include a first artifact signal generated by a 90° RF pulse and a 180° RF pulse applied to the (N-2)th slice and the (N-1)th slice.

The memory 130 may further store an instruction for obtaining a second magnetic resonance signal for the (N-2)th slice, the (N-1)th slice, and the Nth slice by sequentially applying the second pulse sequence to the (N-2)th slice, the (N-1)th slice, and the Nth slice.

The second magnetic resonance signal for the Nth slice may include a second artifact signal generated by the 90° RF pulse and the 180° RF pulse applied to the (N-2)th slice and the (N-1)th slice.

The first artifact signal and the second artifact signal may correspond to pieces of k-space data having opposite signs and the same magnitude.

The memory 130 may store an instruction for obtaining an average value of the pieces of k-space data corresponding to the first magnetic resonance signal obtained for the plurality of slices and the second magnetic resonance signal obtained for the plurality of slices.

When the first magnetic resonance signal obtained for the plurality of slices and the second magnetic resonance signal obtained for the plurality of slices are mixed, the first artifact signal and the second artifact signal having opposite signs and the same magnitude may be offset by each other.

Accordingly, the MRI apparatus 100 may obtain only an image signal for an object from which an artifact has been removed, based on the average value of the first magnetic resonance signal and the second magnetic resonance signal.

According to an embodiment, the MRI apparatus 100 may obtain an image signal based on the average value of the first and second magnetic resonance signals by using a multi-band imaging method instead of a multi-slice imaging method.

Although it has been described above that the first pulse sequence and the second pulse sequence used by the MRI apparatus 100 are spin echo sequences, the first pulse sequence and the second pulse sequence may include gradient echo sequences such as balanced steady-state free precession sequences.

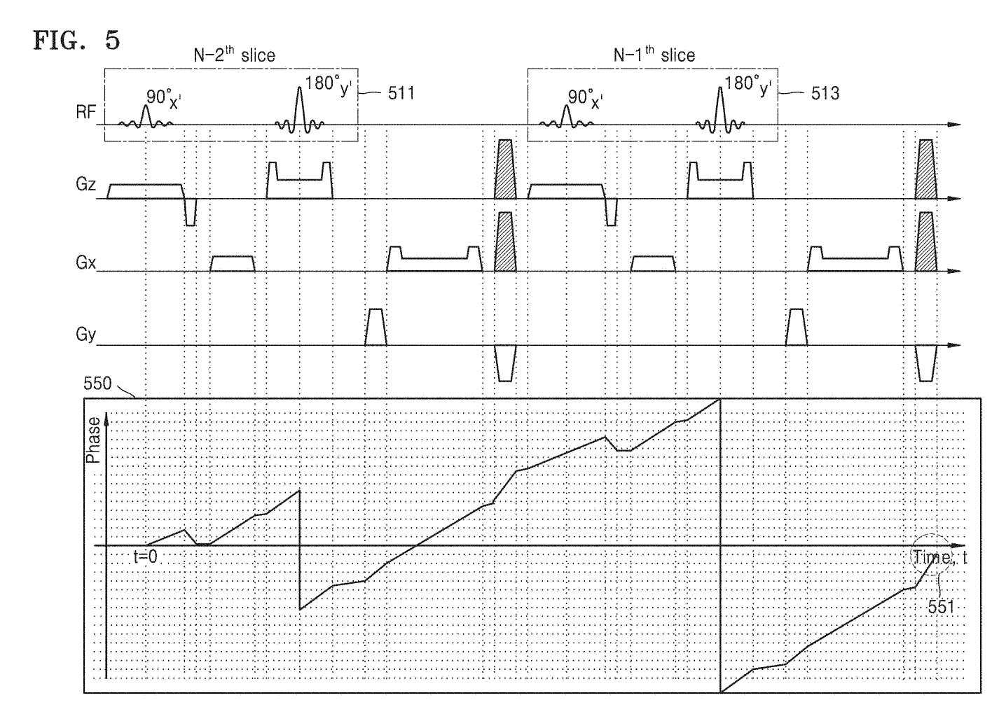

FIG. 5 is a view for explaining an echo path of an artifact signal generated by an RF pulse applied by the MRI apparatus 100 according to an embodiment.

The MRI apparatus 100 according to an embodiment may analyze an echo path of an artifact that appears on an Nth slice when capturing magnetic resonance images in the descending order by multi-slice imaging. Referring to FIG. 5, the MRI apparatus 100 according to an embodiment may display a graph 550 showing a pulse sequence and a phase of a spin.

The pulse sequence shown in FIG. 5 may be the first pulse sequence, which may be for example a spin echo pulse sequence.

In FIG. 5, RF indicates RF pulses applied to an object. Referring to FIG. 5, the RF pulses applied to the object include RF pulses 511 applied to an (N-2)th slice and RF pulses 513 applied to an (N-1)th slice. In FIG. 5, Gz, indicates a gradient applied in a Z-axis direction, Gx indicates a gradient applied in an X-axis direction, and Gy indicates a gradient applied in a Y-axis direction.

Referring to FIG. 5, a 90° RF pulse and a 180° RF pulse applied to the (N-2)th slice have the same signs as a 90° RF pulse and a 180° RF pulse applied to the (N-1)th slice.

According to an embodiment, the MRI apparatus 100 may obtain a first magnetic resonance signal for the (N-2)th slice, the (N-1)th slice, and the Nth slice by sequentially applying the first pulse sequence to the (N-2)th slice, the (N-1)th slice, and the Nth slice.

The first magnetic resonance signal for the Nth slice may include a first artifact signal generated by the RF pulses 511 applied to the (N-2)th slice and the RF pulses 513 applied to the (N-1)th slice. The first artifact signal may be an echo signal generated by the RF pulses 511 and the RF pulses 513 affecting the first portion 301 of FIG. 3.

Referring to the graph 550 of FIG. 5, showing the phase of a spin according to the first pulse sequence, an in-phase portion 551 corresponding to the first artifact signal is shown.

The in-phase portion 551 may correspond to a time point when the phases of spins of the first portion 301 of FIG. 3 have smallest absolute values. At the time point corresponding to the in-phase portion 551, a magnetic resonance signal corresponding to the first artifact signal has a greatest magnitude.

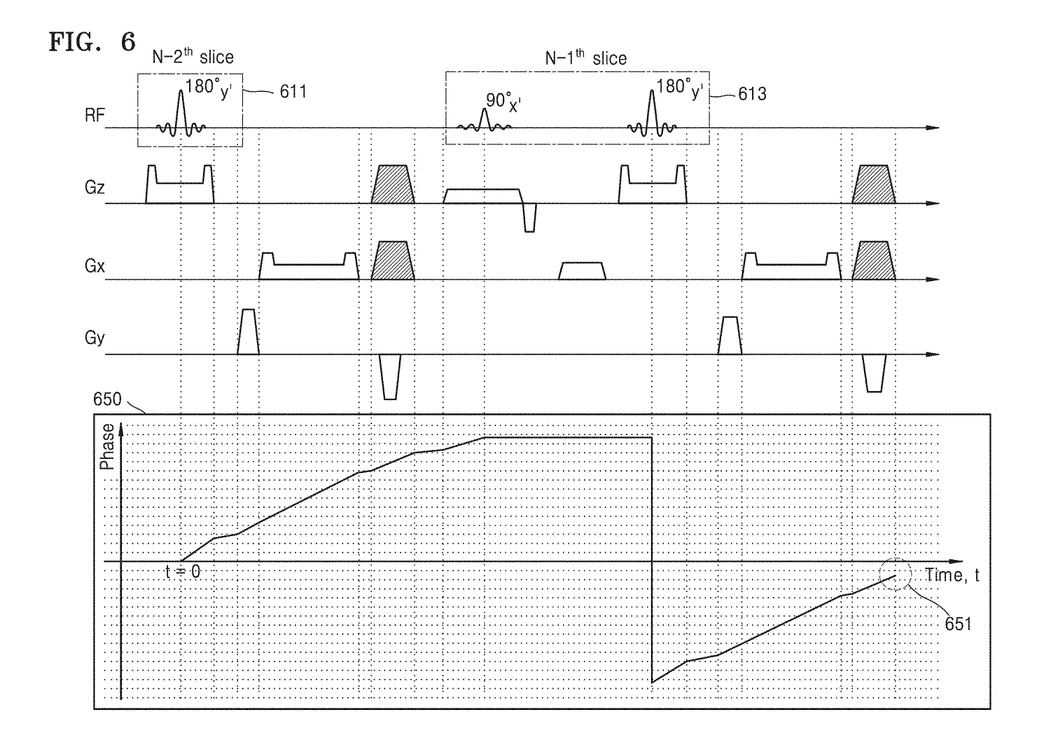

FIG. 6 is a view for explaining an echo path of an artifact signal generated by an RF pulse applied by the MRI apparatus 100 according to an embodiment.

The echo path of FIG. 6 may be another echo path of an artifact that appears on an Nth slice when the MRI apparatus 100 according to an embodiment captures magnetic resonance images in the descending order by multi-slice imaging. Referring to FIG. 6, the MRI apparatus 100 according to an embodiment may display a graph 650 showing a pulse sequence and a phase of a spin.

The pulse sequence shown in FIG. 6 may be the first pulse sequence, which may be for example a spin echo pulse sequence.

In FIG. 6, RF indicates RF pulses applied to an object. Referring to FIG. 6, the RF pulses applied to the object include an RF pulse 611 applied to an (N-2)th slice and RF pulses 613 applied to an (N-1)th slice. In FIG. 6, Gz indicates a gradient applied in a Z-axis direction, Gx indicates a gradient applied in an X-axis direction, and Gy indicates a gradient applied in a Y-axis direction.

Referring to FIG. 6, to analyze an echo path that affects a signal for the second portion 303 of FIG. 3, the RF pulse 611 applied to the (N-2)th slice includes only the 180° RF pulse. The 180° RF pulse applied to the (N-2)th slice has the same sign as the 90° RF pulse and the 180° RF pulse applied to the (N-1)th slice.

According to an embodiment, the MRI apparatus 100 may obtain a first magnetic resonance signal for the (N-2)th slice, the (N-1)th slice, and the Nth slice by sequentially applying the first pulse sequence to the (N-2)th slice, the (N-1)th slice, and the Nth slice.

The first magnetic resonance signal for the Nth slice may include a first artifact signal generated by the RF pulse 611 applied to the (N-2)th slice and the RF pulses 613 applied to the (N-1)th slice.

The first artifact signal may be, for example, an echo signal generated by the RF pulse 611 and the RF pulses 613 affecting the second portion 303 of FIG. 3.

Referring to the graph 650 of FIG. 6, showing the phase of a spin according to the first pulse sequence, an in-phase portion 651 corresponding to the first artifact signal is shown.

The in-phase portion 651 may correspond to a time point when the phases of spins of the second portion 303 of FIG. 3 have smallest absolute values. At the time point corresponding to the in-phase portion 651, a magnetic resonance signal corresponding to the first artifact signal has a greatest magnitude.

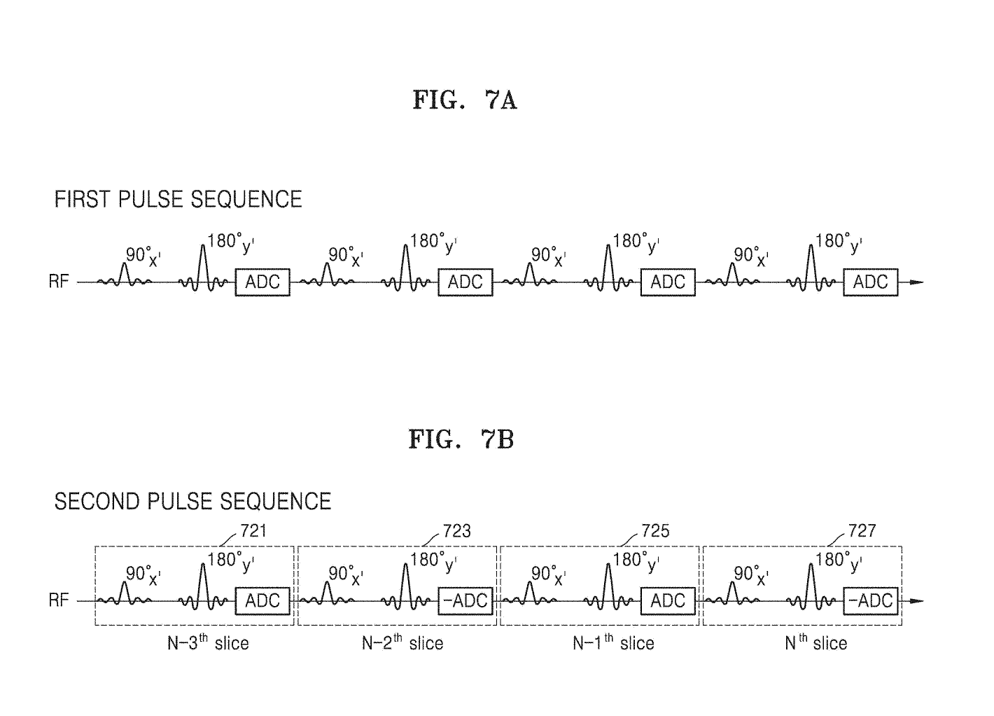

FIG. 7A is a diagram for illustrating the first pulse sequence used by the MRI apparatus 100 according to an embodiment.

The first pulse sequence shown in FIG. 7A is a spin echo sequence that the MRI apparatus 100 uses to acquire a magnetic resonance image based on multi-slice imaging.

The 90° RF pulse and the 180° RF pulse included in the first pulse sequence may be have the same sign when applied to adjacent slices from among the plurality of slices.

FIG. 7B is a diagram for illustrating the second pulse sequence used by the MRI apparatus 100 according to an embodiment.

The second pulse sequence shown in FIG. 7B is a spin echo sequence that the MRI apparatus 100 uses to acquire a magnetic resonance image based on multi-slice imaging.

Referring to FIG. 7B, the 90° RF pulse and the 180° RF pulse included in the second pulse sequence according to an embodiment may having opposite signs when applied to adjacent slices from among the plurality of slices.

For example, an RF pulse 721 that is applied to an (N-3)th slice has an opposite sign to a sign of an RF pulse 723 that is applied to an (N-2)th slice. The RF pulse 723 that is applied to the (N-2)th slice has an opposite sign to a sign of an RF pulse 725 that is applied to an (N-1)th slice. Similarly, the RF pulse 725 that is applied to the (N-1)th slice has an opposite sign to a sign of an RF pulse 727 that is applied to an Nth slice.

The signal receiver of the MRI apparatus 100 may receive echo signals respectively corresponding to adjacent slices in opposite directions when receiving echo signals respectively corresponding to a plurality of slices. The signal receiver may have a function of transmitting and receiving an RF signal.

For convenience, in FIG. 7B, an echo signal receiving direction of the signal receiver when the signal receiver receives echo signals corresponding to the (N-3)th slice and the (N-1)th slice is illustrated as a positive sign ADC, and an echo signal receiving direction of the signal receiver when the signal receiver receives echo signals corresponding to the (N-2)th slice and the N-th slice is illustrated as a negative sign—ADC.

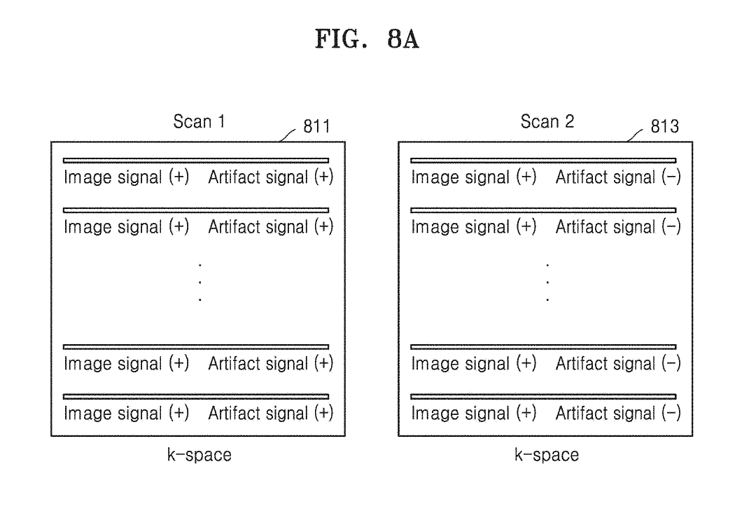

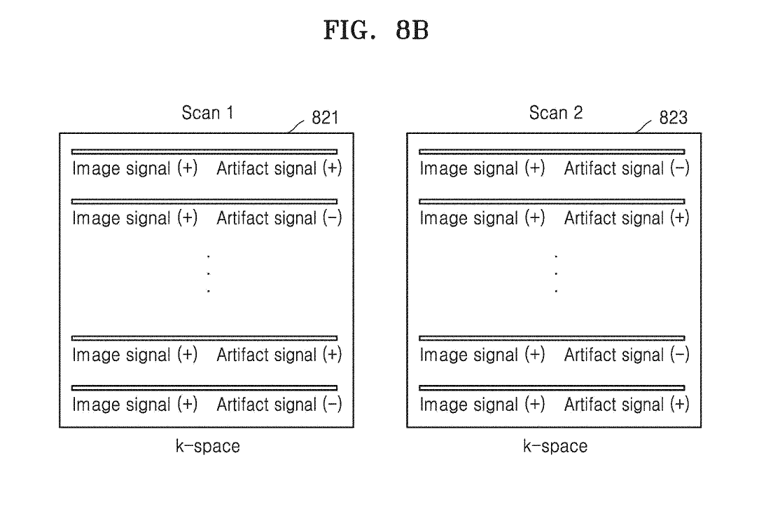

FIG. 8A illustrates pieces of k-space data respectively corresponding to the first magnetic resonance signal and the second magnetic resonance signal obtained by the MRI apparatus 100 according to an embodiment.

FIG. 8A illustrates first k-space data 811 and second k-space data 813.

The first k-space data 811 may correspond to the first magnetic resonance signal obtained by applying the first pulse sequence to the plurality of slices of the object. The second k-space data 813 may correspond to the second magnetic resonance signal obtained by applying the second pulse sequence to the plurality of slices of the object.

An image signal included in the first k-space data 811 has the same sign and the same magnitude as an image signal included in the second k-space data 813.

An artifact signal included in the first k-space data 811 has a different sign from, and the same magnitude as, an artifact signal included in the second k-space data 813. The MRI apparatus 100 may make k-space data corresponding to an artifact signal zero (0), by mixing the first k-space data 811 and the second k-space data 813.

FIG. 8B illustrates pieces of k-space data respectively corresponding to the first magnetic resonance signal and the second magnetic resonance signal obtained by the MRI apparatus 100 according to an embodiment.

FIG. 8B illustrates first k-space data 821 and second k-space data 823.

The first k-space data 821 may correspond to the first magnetic resonance signal obtained by applying the first pulse sequence to the plurality of slices of the object. The second k-space data 823 may correspond to the second magnetic resonance signal obtained by applying the second pulse sequence to the plurality of slices of the object.

An image signal included in the first k-space data 821 has the same sign and the same magnitude as an image signal included in the second k-space data 823. An artifact signal included in each line of the first k-space data 821 has a different sign from, and the same magnitude as, an artifact signal included in each line of the second k-space data 823.

The MRI apparatus 100 may make k-space data corresponding to an artifact signal zero (0), by mixing the first k-space data 821 and the second k-space data 823.

In FIGS. 8A and 8B, Scan 1 may refer to capturing of a magnetic resonance image by the MRI apparatus 100 by using the first pulse sequence, and Scan 2 may refer to capturing of a magnetic resonance image by the MRI apparatus 100 by using the second pulse sequence.

Scan 1 and Scan 2 may include acquiring an average value by performing a plurality of scans with respect to a plurality of slices. The performing of the plurality of scans includes repeating acquisition of the entire line data of a k-space corresponding to the plurality of slices in the descending order or the ascending order (long-term average). The performing of the plurality of scans also includes repeating acquisition of data of one line of a k-space corresponding to the plurality of slices in the descending order or the ascending order and equally applying the repetition to the other lines (short-term average).

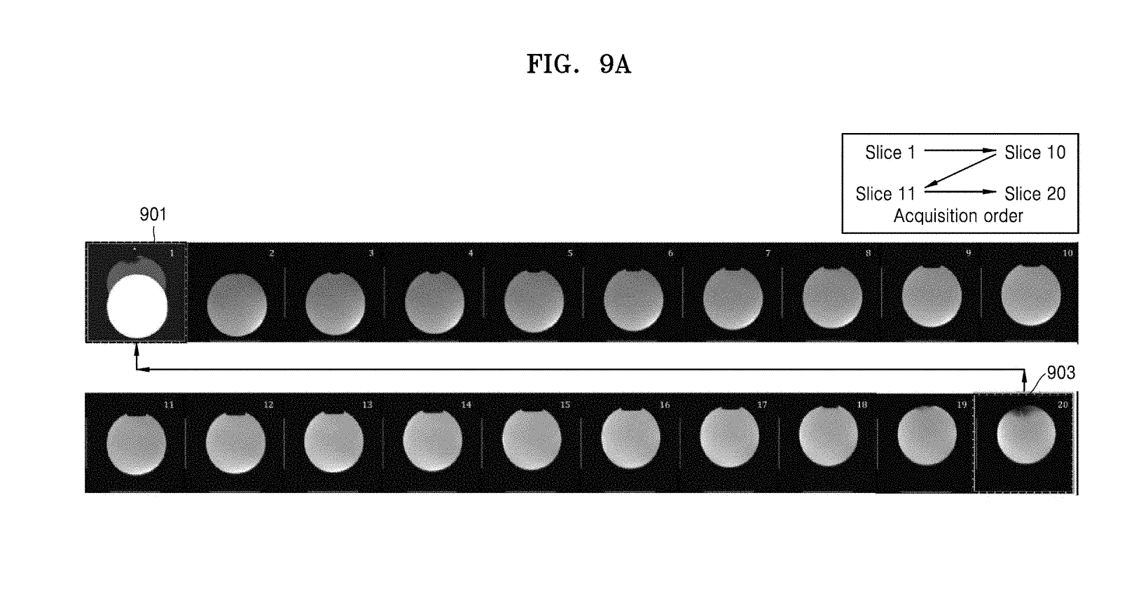

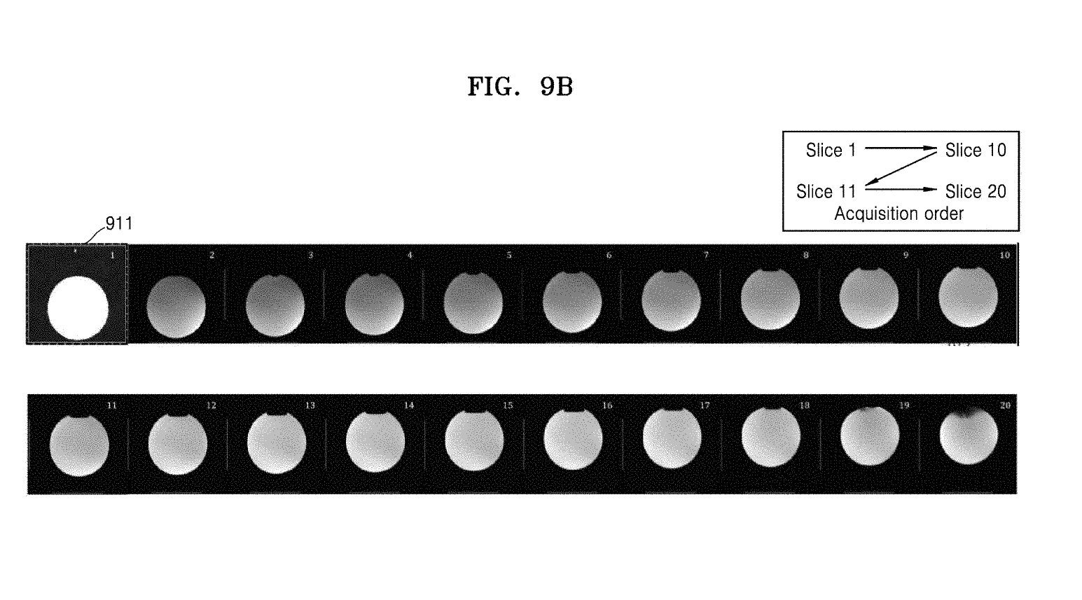

FIG. 9A illustrates a plurality of sectional images acquired based on the first magnetic resonance signal by the MRI apparatus 100 according to an embodiment.

According to an embodiment, FIG. 9A illustrates a plurality of sectional images corresponding to a plurality of slices acquired based on a spin echo pulse sequence according to multi-slice imaging by the MRI apparatus 100. The plurality of sectional images are illustrated in an acquisition order of the plurality of slices. The plurality of sectional images may correspond to a T1 image.

Referring to FIG. 9A, the MRI apparatus 100 may sequentially acquire a total of 20 sectional images starting from a first sectional image 901 corresponding to a first slice to a second sectional image 903 corresponding to a twentieth slice, based on the first pulse sequence. A greatest artifact may be generated in the first sectional image 901, based on pieces of data of adjacent slices. For example, the first sectional image 901 may include a similar artifact to the second sectional image 903.

FIG. 9B illustrates a plurality of sectional images acquired based on an average value of the first and second magnetic resonance signals by the MRI apparatus 100 according to an embodiment.

According to an embodiment, FIG. 9B illustrates a plurality of sectional images corresponding to a plurality of slices acquired based on a spin echo pulse sequence according to multi-slice imaging by the MRI apparatus 100. The plurality of sectional images are illustrated in an acquisition order of the plurality of slices. The plurality of sectional images may correspond to a T1 image.

Referring to FIG. 9B, the MRI apparatus 100 may obtain a first magnetic resonance signal corresponding to the first through twentieth slices, based on the first pulse sequence. The MRI apparatus 100 may also obtain a second magnetic resonance signal corresponding to the first through twentieth slices, based on the second pulse sequence. The MRI apparatus 100 may acquire a total of 20 sectional images, based on an average value of the first magnetic resonance signal and the second magnetic resonance signal. In contrast with the first sectional image 901 of FIG. 9A, a first sectional image 911 may be an image from which an artifact generated based on pieces of data of adjacent slices has been removed.

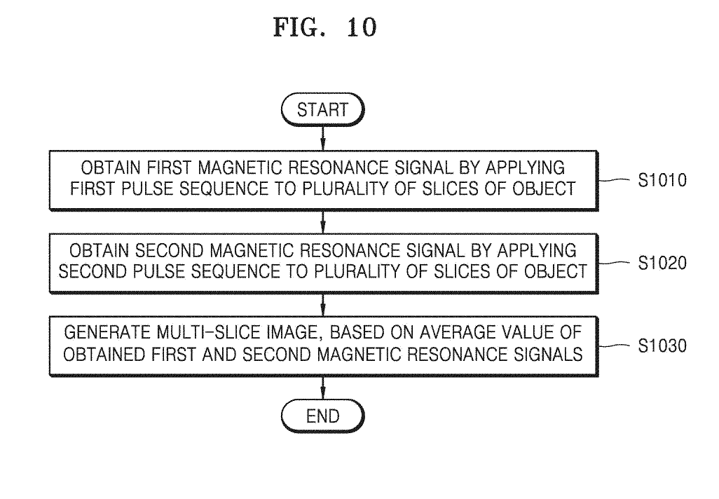

FIG. 10 is a flowchart of a method, performed by the MRI apparatus 100, of generating a magnetic resonance image, according to an embodiment.

In operation S1010, the MRI apparatus 100 may obtain a first magnetic resonance signal by applying a first pulse sequence to a plurality of slices of an object.

In operation S1020, the MRI apparatus 100 may obtain a second magnetic resonance signal by applying a second pulse sequence to the plurality of slices of the object.

In operation S1030, the MRI apparatus 100 may generate a multi-slice image, based on an average value of the obtained first and second magnetic resonance signals.

The first pulse sequence and the second pulse sequence may be spin echo sequences including a 90° RF pulse and a 180° RF pulse applied to each of the plurality of slices according to an order on a space in which the plurality of slices are located.

The 90° RF pulse and the 180° RF pulse included in the second pulse sequence according to an embodiment may have opposite signs when applied to adjacent slices from among the plurality of slices.

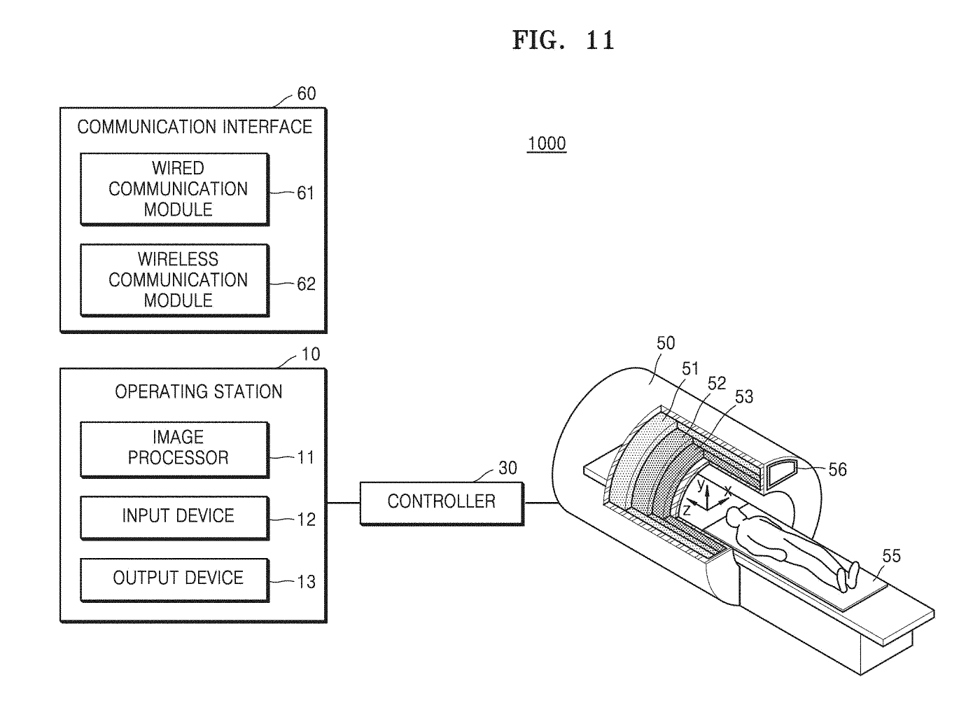

FIG. 11 is a schematic diagram of an MRI system 1000 according to an embodiment.

Referring to FIG. 11, the MRI system 1000 may include an operating station 10, a controller 30, and a scanner 50. The controller 30 may be independently separated from the operating station 10 and the scanner 50. Furthermore, the controller 30 may be separated into a plurality of sub-components and incorporated into the operating station 10 and the scanner 50 in the MRI system 1000. Operations of the components in the MRI system 1000 will now be described in detail.

The scanner 50 may be formed to have a cylindrical shape, for example a shape of a bore, having an empty inner space into which an object may be inserted. A static magnetic field and a gradient magnetic field are created in the inner space of the scanner 50, and an RF signal is emitted toward the inner space.

The scanner 50 may include a static magnetic field generator 51, a gradient magnetic field generator 52, an RF coil unit 53, a table 55, and a display 56. The static magnetic field generator 51 creates a static magnetic field for aligning magnetic dipole moments of atomic nuclei of the object in a direction of the static magnetic field. The static magnetic field generator 51 may be formed as a permanent magnet or superconducting magnet using a cooling coil.

The gradient magnetic field generator 52 is connected to the controller 30 and generates a gradient magnetic field by applying a gradient to a static magnetic field in response to a control signal received from the controller 30. The gradient magnetic field generator 52 includes X, Y, and Z coils for generating gradient magnetic fields in X-axis, Y-axis, and Z-axis directions crossing each other at right angles, and generates a gradient signal according to a position of a region being imaged so as to differently induce resonance frequencies according to regions of the object.

The RF coil unit 53 connected to the controller 30 may emit an RF signal toward the object in response to a control signal received from the controller 30 and receive an magnetic resonance signal emitted from the object. In detail, the RF coil unit 53 may transmit, toward atomic nuclei of the object having precessional motion, an RF signal having the same frequency as that of the precessional motion, stop transmitting the RF signal, and then receive an magnetic resonance signal emitted from the object.

The RF coil unit 53 may be formed as a transmitting RF coil for generating an electromagnetic wave having an RF corresponding to the type of an atomic nucleus, a receiving RF coil for receiving an electromagnetic wave emitted from an atomic nucleus, or one transmitting/receiving RF coil serving both functions of the transmitting RF coil and receiving RF coil. Furthermore, in addition to the RF coil unit 53, a separate coil may be attached to the object. Examples of the separate coil may include a head coil, a spine coil, a torso coil, and a knee coil according to a region being imaged or to which the separate coil is attached.

The display 56 may be disposed outside and inside the scanner 50. The display 56 is also controlled by the controller 30 to provide a user or the object with information related to medical imaging.

The display 56 may include the display 110 of FIG. 4.

Furthermore, the scanner 50 may include an object monitoring information acquisition unit configured to acquire and transmit monitoring information about a state of the object. For example, the object monitoring information acquisition unit may acquire monitoring information related to the object from a camera for capturing images of a movement or position of the object, a respiration measurer for measuring the respiration of the object, an ECG measurer for measuring the electrical activity of the heart, or a temperature measurer for measuring a temperature of the object and transmit the acquired monitoring information to the controller 30. The controller 30 may in turn control an operation of the scanner 50 based on the monitoring information. Operations of the controller 30 will now be described in more detail.

The controller 150 may control overall operations of the scanner 50.

The controller 30 may control a sequence of signals formed in the scanner 50. The controller 30 may control the gradient magnetic field generator 52 and the RF coil unit 53 according to a pulse sequence received from the operating station 10 or a designed pulse sequence.

A pulse sequence may include all pieces of information required to control the gradient magnetic field generator 52 and the RF coil unit 53. For example, the pulse sequence may include information about a strength, a duration, and application timing of a pulse signal applied to the gradient magnetic field generator 52.

The controller 30 may control a waveform generator for generating a gradient wave, for example an electrical pulse according to a pulse sequence, and a gradient amplifier for amplifying the generated electrical pulse and transmitting the same to the gradient magnetic field generator 52. Thus, the controller 30 may control formation of a gradient magnetic field by the gradient magnetic field generator 52.

Furthermore, the controller 30 may control an operation of the RF coil unit 53. For example, the controller 30 may supply an RF pulse having a resonance frequency to the RF coil unit 53 that emits an RF signal toward the object, and receive a magnetic resonance signal received by the RF coil unit 53. In this case, the controller 30 may adjust emission of an RF signal and reception of a magnetic resonance signal according to an operating mode by controlling an operation of a switch, for example a T/R switch, for adjusting transmitting and receiving directions of the RF signal and the magnetic resonance signal based on a control signal.

The controller 30 may control a movement of the table 55 where the object is placed. Before MRI is performed, the controller 30 may move the table 55 according to which region of the object is to be imaged.

The controller 30 may also control the display 56. For example, the controller 30 control the on/off state of the display 56 or a screen to be output on the display 56 according to a control signal.

The controller 30 may be formed as an algorithm for controlling operations of the components in the MRI system 1000, a memory for storing data in the form of a program, and a processor for performing the above-described operations by using the data stored in the memory. In this case, the memory and the processor may be implemented as separate chips. In another embodiment, the memory and processor may be incorporated into a single chip.

The controller 30 may include the processor 120 and the memory 130 of FIG. 4.

The operating station 10 may control overall operations of the MRI system 1000 and include an image processor 11, an input device 12, and an output device 13.

The image processor 11 may control the memory to store a magnetic resonance signal received from the controller 30, and generate image data with respect to the object from the stored magnetic resonance signal by applying an image reconstruction technique by using an image processor.

For example, when a k space, for example, also referred to as a Fourier space or a frequency space, of the memory is filled with digital data to complete k-space data, the image processor 11 may reconstruct image data from the k-space data by applying various image reconstruction techniques, for example, by performing inverse Fourier transform on the k-space data, by using the image processor.

Furthermore, the image processor 11 may perform various signal processing operations on magnetic resonance signals in parallel. For example, the image processor may perform signal processing on a plurality of magnetic resonance signals received by a multi-channel RF coil in parallel to rearrange the plurality of magnetic resonance signals into image data. In addition, the image processor 11 may store not only the image data in the memory, or the controller 30 may store the same in an external server via a communication interface 60 as will be described below.

The input device 12 may receive, from the user, a control command for controlling the overall operations of the MRI system 1000. For example, the input device 12 may receive, from the user, object information, parameter information, a scan condition, and information about a pulse sequence. The input device 12 may be a keyboard, a mouse, a track ball, a voice recognizer, a gesture recognizer, a touch screen, or any other input device.

The output device 13 may output image data generated by the image processor 11. The output device 13 may also output a user interface (UI) configured so that the user may input a control command related to the MRI system 1000. The output device 13 may be, for example, a speaker, a printer, a display, or any other output device.

Furthermore, although FIG. 11 shows that the operating station 10 and the controller 30 are separate components, the operating station 10 and the controller 30 may be included in a single device as described above. Furthermore, processes respectively performed by the operating station 10 and the controller 30 may be performed by another component. For example, the image processor 11 may convert a magnetic resonance signal received from the controller 30 into a digital signal, or the controller 30 may directly perform the conversion of the magnetic resonance signal into the digital signal.

The MRI system 1000 may further include a communication interface 60 and be connected to an external device such as a server, a medical apparatus, and a portable device, for example a smartphone, a tablet PC, a wearable device, etc., via the communication interface 60.

The communication interface 60 may include at least one component that enables communication with an external device. For example, the communication interface 60 may include at least one of a local area communication module, a wired communication module 61, and a wireless communication module 62.

The communication interface 60 may receive a control signal and data from an external device and transmit the received control signal to the controller 30 so that the controller 30 may control the MRI system 1000 according to the received signal.

In another embodiment, by transmitting a control signal to an external device via the communication interface 60, the controller 30 may control the external device according to the control signal.

For example, the external device may process data of the external device according to a control signal received from the controller 30 via the communication interface 60.

A program for controlling the MRI system 1000 may be installed on the external device and may include instructions for performing some or all of the operations of the controller 30.

The program may be preinstalled on the external device, or a user of the external device may download the program from a server providing an application for installation. The server providing an application may include a recording medium having the program recorded thereon. Programs stored in a server may be downloaded to another device or are downloadable. Computer-readable programs are downloadable in a remote data processing system so as to be used together with the remote data processing system by a computer readable recording medium.

When a multi-slice magnetic resonance image of an object is captured, a magnetic resonance image from which an artifact resulting from a signal of adjacent slices has been removed may be generated.

Embodiments may be implemented through non-transitory computer-readable recording media having recorded thereon computer-executable instructions and data. The instructions may be stored in the form of program codes, and when executed by a processor, may cause the processor to generate a predetermined program module to perform a specific operation. Furthermore, when being executed by the processor, the instructions may cause the processor to perform specific operations according to the embodiments. Some embodiments may be implemented as a computer program or a computer program product including instructions executable by a computer.

While the present disclosure has been particularly shown and described with reference to exemplary embodiments thereof, it will be understood by those of ordinary skill in the art that various changes in form and details may be made therein without departing from the spirit and scope of the present disclosure as defined by the following claims.

What is claimed is:

1. A magnetic resonance imaging (MRI) apparatus comprising:
a processor; and
a memory connected to the processor and configured to store an instruction which, when executed by the processor, causes the processor to:
acquire a first magnetic resonance signal by applying a first pulse sequence to a plurality of slices of an object;
acquire a second magnetic resonance signal by applying a second pulse sequence to the plurality of slices; and
generate a multi-slice image, based on an average value of the acquired first magnetic resonance signal and the acquired second magnetic resonance signal,
wherein the first pulse sequence comprises a first spin echo sequence including a first 90° radio frequency (RF) pulse and a first 180° RF pulse applied to each of the plurality of slices according to an order of the plurality of slices in a space where the plurality of slices are located,
wherein the second pulse sequence comprises a second spin echo sequence including a second 90° RF pulse and a second 180° RF pulse applied to each of the plurality of slices according to the order of the plurality of slices in the space where the plurality of slices are located,
wherein the second 90° RF pulse is applied having opposite signs to adjacent slices from among the plurality of slices, and
wherein the second 180° RF pulse is applied having opposite signs to the adjacent slices from among the plurality of slices.

2. The MRI apparatus of claim 1, wherein a sign of the first 90° RF pulse is applied having same signs to the adjacent slices from among the plurality of slices, and a sign of the first 180° RF pulse is applied having same signs to the adjacent slices from among the plurality of slices.

3. The MRI apparatus of claim 1, wherein:
the memory is further configured to store an instruction which, when executed by the processor, causes the processor to:
receive a plurality of first echo signals corresponding to the plurality of slices according to the order of the plurality of slices in the space where the plurality of slices are located, by applying the first pulse sequence to the plurality of slices; and
receive a plurality of second echo signals corresponding to the plurality of slices according to the order of the plurality of slices in the space where the plurality of slices are located, by applying the second pulse sequence to the plurality of slices, and
the MRI apparatus further comprises a signal receiver configured to receive the first echo signal and the second echo signal.

4. The MRI apparatus of claim 3, wherein the memory is further configured to store an instruction which, when executed by the processor, causes the processor to receive second echo signals corresponding to the adjacent slices in opposite directions when receiving the plurality of second echo signals.

5. The MRI apparatus of claim 3, further comprising an analog-to-digital converter (ADC) configured to perform analog-to-digital conversion with respect to the plurality of first echo signals and the plurality of second echo signals received by the signal receiver.

6. The MRI apparatus of claim 1, wherein the memory is further configured to store an instruction which, when executed by the processor, causes the processor to display a phase of a spin according to at least a portion of the first pulse sequence.

7. The MRI apparatus of claim 1, wherein:
the memory is further configured to store an instruction which, when executed by the processor, causes the processor to acquire a first magnetic resonance signal corresponding to an (N-2)th slice, a first magnetic resonance signal corresponding to an (N-1)th slice, and a first magnetic resonance signal corresponding to an N-th slice by sequentially applying the first pulse sequence to the (N-2)th slice, the (N-1)th slice, and the N-th slice, and
the first magnetic resonance signal corresponding to the N-th slice comprises a first artifact signal generated by the first 90° RF pulse and the first 180° RF pulse applied to the (N-2)th slice and the (N-1)th slice.

8. The MRI apparatus of claim 7, wherein:
the memory is further configured to store an instruction which, when executed by the processor, causes the processor to acquire a second magnetic resonance signal corresponding to the (N-2)th slice, a second magnetic resonance signal corresponding to the (N-1)th slice, and a second magnetic resonance signal corresponding to the N-th slice by sequentially applying the second pulse sequence to the (N-2)th slice, the (N-1)th slice, and the N-th slice,
the second magnetic resonance signal for the N-th slice comprises a second artifact signal generated by the second 90° RF pulse and the second 180° RF pulse applied to the (N-2)th slice and the (N-1)th slice,
the first artifact signal corresponds to a first piece of k-space data,
the second artifact signal corresponds to a second piece of k-space data,
a sign of the first piece of k-space data is opposite to a sign of the second piece of k-space data, and
a magnitude of the first piece of k-space data is equal to a magnitude of the second piece of k-space data.

9. The MRI apparatus of claim 8, wherein an in-phase time of spins corresponding to the first artifact signal corresponds to an in-phase time of spins corresponding to the second artifact signal.

10. The MRI apparatus of claim 1, further comprising a display,
wherein the memory is further configured to store an instruction which, when executed by the processor, causes the processor to control the display to display the generated multi-slice image.

11. A method of generating a magnetic resonance image from which an artifact due to a signal of adjacent slices has been removed, when a multi-slice magnetic resonance image of an object is captured, the method comprising:
acquiring a first magnetic resonance signal by applying a first pulse sequence to a plurality of slices of the object;
acquiring a second magnetic resonance signal by applying a second pulse sequence to the plurality of slices; and
generating the multi-slice magnetic resonance image, based on an average value of the acquired first magnetic resonance signal and the acquired second magnetic resonance signal,
wherein the first pulse sequence comprises a first spin echo sequence including a first 90° radio frequency (RF) pulse and a first 180° RF pulse applied to each of the plurality of slices according to an order of the plurality of slices in a space where the plurality of slices are located,
wherein the second pulse sequence comprises a second spin echo sequence including a second 90° RF pulse and a second 180° RF pulse applied to each of the plurality of slices according to the order of the plurality of slices in the space where the plurality of slices are located,
wherein the second 90° RF pulse is applied having opposite signs to adjacent slices from among the plurality of slices, and
wherein the second 180° RF pulse is applied having opposite signs to the adjacent slices from among the plurality of slices.

12. The method of claim 11, wherein a sign of the first 90° RF pulse is applied having same signs to the adjacent slices from among the plurality of slices, and a sign of the first 180° RF pulse is applied having same signs to the adjacent slices from among the plurality of slices.

13. The method of claim 11, wherein the acquiring of the first magnetic resonance signal comprises receiving, from a signal receiver, a plurality of first echo signals corresponding to the plurality of slices according to the order of the plurality of slices in the space where the plurality of slices are located, by applying the first pulse sequence to the plurality of slices, and
the acquiring of the second magnetic resonance signal comprises receiving, from the signal receiver, a plurality of second echo signals corresponding to the plurality of slices according to the order of the plurality of slices in the space where the plurality of slices are located, by applying the second pulse sequence to the plurality of slices.

14. The method of claim 13, wherein the receiving of the second echo signal comprises receiving second echo signals corresponding to the adjacent slices in opposite directions when receiving the plurality of second echo signals.

15. The method of claim 14, further comprising:
performing analog-to-digital conversion on the received plurality of first echo signals using an analog-to-digital converter (ADC); and
performing analog-to-digital conversion on the received plurality of second echo signals using the ADC.

16. The method of claim 11, further comprising displaying a phase of a spin according to at least a portion of the first pulse sequence.

17. The method of claim 11, wherein the acquiring of the first magnetic resonance signal comprises acquiring the a first magnetic resonance signal corresponding to an (N-2)th slice, a first magnetic resonance signal corresponding to an (N-1)th slice, and a first magnetic resonance signal corresponding to an N-th slice by sequentially applying the first pulse sequence to the (N-2)th slice, the (N-1)th slice, and the N-th slice, and
the first magnetic resonance signal corresponding to the N-th slice comprises a first artifact signal generated by the first 90° RF pulse and the first 180° RF pulse applied to the (N-2)th slice and the (N-1)th slice.

18. The method of claim 17, wherein:
the acquiring of the second magnetic resonance signal comprises acquiring a second magnetic resonance signal corresponding to the (N-2)th slice, a second magnetic resonance signal corresponding to the (N-1)th slice, and a second magnetic resonance signal corresponding to the N-th slice by sequentially applying the second pulse sequence to the (N-2)th slice, the (N-1)th slice, and the N-th slice,
the second magnetic resonance signal for the N-th slice comprises a second artifact signal generated by the second 90° RF pulse and the second 180° RF pulse applied to the (N-2)th slice and the (N-1)th slice,
the first artifact signal corresponds to a first piece of k-space data,
the second artifact signal corresponds to a second piece of k-space data,
a sign of the first piece of k-space data is opposite to a sign of the second piece of k-space data, and
a magnitude of the first piece of k-space data is equal to a magnitude of the second piece of k-space data.

19. The method of claim 18, wherein an in-phase time of spins corresponding to the first artifact signal corresponds to an in-phase time of spins corresponding to the second artifact signal.

20. A computer program product comprising a non-transitory computer-readable recording medium having recorded thereon a computer program, which, when executed by a computer, causes the computer to perform the method of claim 11.
